(19) United States
(12) Patent Application Publication
(10) Pub. No.: US 2021/0318686 A1
(43) Pub. Date: Oct. 14, 2021

(54) VEHICLE MOTION PLANNING USING A MANIFOLD DESCRIPTION OF ROAD SURFACE GEOMETRY

(71) Applicant: Robert Bosch GmbH, Stuttgart (DE)

(72) Inventors: Felix Geyer, Palo Alto, CA (US); Jason Scott Hardy, Union City, CA (US)

(21) Appl. No.: 16/845,760

(22) Filed: Apr. 10, 2020

(51) Int. Cl. G05D 1/02; G01C 21/32

(52) U.S. Cl. CPC G05D 1/0219; G05D 1/0278; G01C 21/32

(57) ABSTRACT

Systems and methods for vehicle motion planning. The system includes an electronic controller configured to access a manifold describing a driving surface in three dimensions from a memory, perform parameterization of the manifold to obtain a plurality of local charts describing the driving surface in two dimensions, determine a driving path of a vehicle based using the plurality of local charts, and generate a command to navigate the vehicle along the driving path.

Embodiments relate to planning vehicle motions based upon local road surface geometry.

### BACKGROUND

Vehicle motions, such as direction of travel, turning actions, reversing actions, and others, are currently planned in autonomous vehicles in two dimensions. Often, the vehicle's driving environment is projected onto a linear surface to allow planning in two-dimensional (“2-D”) Euclidean space. For example, the vehicle's driving environment may be projected along a local gravitational direction. A vehicle's motion path is planned using a reference point of the vehicle in the plane on which the vehicle travels. However, state-of-the-art vehicle motion planning systems fail to take into account local road surface geometry.

### SUMMARY

Therefore, among other objects, one object of some embodiments is to improve upon state-of-the-art vehicle motion planning systems by approximating local road surface geometry and incorporating the local road surface geometry into vehicle motion planning. This helps to increase the accuracy of distance and velocity calculations (or determinations) in the motion planning phase without additional computational overhead. The local road surface geometry is described as using a mathematical manifold, or a topological space that locally resembles Euclidean space near each point in the manifold. Using manifold descriptions of the driving surface helps an autonomous vehicle to plan a path along complex road geometry and helps to account for grade-dependent distance differences while reducing computational overhead of the vehicle motion planning system.

One embodiment provides a vehicle motion planning system. The system includes an electronic controller configured to access a manifold describing a driving surface in three dimensions from a memory, perform parameterization of the manifold to obtain a plurality of local charts describing the driving surface in two dimensions, determine a driving path of a vehicle based using the plurality of local charts, and generate a command to navigate the vehicle along the driving path.

Another embodiment provides a method for planning a vehicle motion. In one example, the method includes accessing, with an electronic controller, a manifold describing a driving surface in three dimensions from a memory; and performing, with the electronic controller, parameterization of the manifold to obtain a plurality of local charts describing the driving surface in two dimensions. The method also includes determining, with the electronic controller, a driving path of a vehicle based using the plurality of local charts; and generating, with the electronic controller, a command to navigate the vehicle along the driving path.

These and other features, aspects, and advantages will be apparent from a reading of the following detailed description and a review of the associated drawings. It is to be understood that both the foregoing general description and the following detailed description are explanatory and do not restrict aspects as claimed.

### BRIEF DESCRIPTION OF THE DRAWINGS

FIG. 1 illustrates a vehicle motion planning system according to one embodiment.

FIG. 2 illustrates an electronic controller according to one embodiment.

FIG. 3A illustrates a driving surface in three dimensions according to one embodiment.

FIG. 3B illustrates a driving surface in two dimensions according to one embodiment.

FIG. 4A illustrates a helix driving surface in three dimensions according to one embodiment.

FIG. 4B illustrates a helix driving surface in two dimensions according to one embodiment.

FIG. 5 illustrates a method of planning a vehicle motion according to one embodiment.

### DETAILED DESCRIPTION

One or more embodiments are described and illustrated in the following description and accompanying drawings. These embodiments are not limited to the specific details provided herein and may be modified in various ways. Furthermore, other embodiments may exist that are not described herein. Also, the functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way, but may also be configured in ways that are not listed. Furthermore, some embodiments described herein may include one or more electronic processors configured to perform the described functionality by executing instructions stored in non-transitory, computer-readable medium. Similarly, embodiments described herein may be implemented as non-transitory, computer-readable medium storing instructions executable by one or more electronic processors to perform the described functionality. As used in the present application, “non-transitory computer-readable medium” comprises all computer-readable media but does not consist of a transitory, propagating signal. Accordingly, non-transitory computer-readable medium may include, for example, a hard disk, a CD-ROM, an optical storage device, a magnetic storage device, a ROM (Read Only Memory), a RAM (Random Access Memory), register memory, a processor cache, or any combination thereof.

In addition, the phraseology and terminology used herein is for the purpose of description and should not be regarded as limiting. For example, the use of “including,” “containing,” “comprising,” “having,” and variations thereof herein is meant to encompass the items listed thereafter and equivalents thereof as well as additional items. The terms “connected” and “coupled” are used broadly and encompass both direct and indirect connecting and coupling. Further, “connected” and “coupled” are not restricted to physical or mechanical connections or couplings and can include electrical connections or couplings, whether direct or indirect. In addition, electronic communications and notifications may be performed using wired connections, wireless connections, or a combination thereof and may be transmitted directly or through one or more intermediary devices over various types of networks, communication channels, and connections. Moreover, relational terms such as first and second, top and bottom, and the like may be used herein solely to distinguish one entity or action from another entity or action without necessarily requiring or implying any actual such relationship or order between such entities or actions.

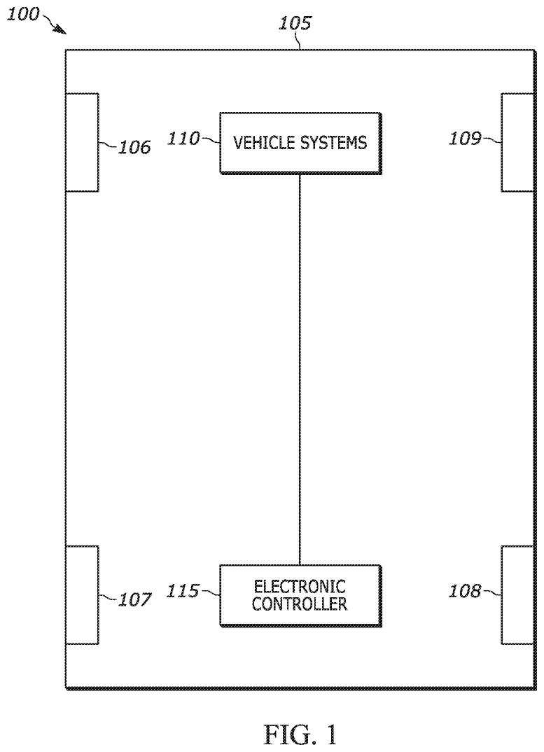

FIG. 1 illustrates a vehicle motion planning system 100 for a vehicle 105 according to one embodiment. The vehicle includes wheels 106, 107, 108, and 109. The vehicle motion planning system 100 includes a plurality of vehicle systems 110 and an electronic controller 115.

The plurality of vehicle systems 110 includes, for example, a steering system, a braking system, a propulsion system, a navigation system, and other systems used to operate and/or control the vehicle 105. In one example, the plurality of vehicle systems 110 are configured to guide the vehicle 105 along a driving path, maintain proper vehicle speed (e.g., propel the vehicle 105 at a legal driving speed for a section of road), control the vehicle 105 to stop and start driving along the driving path at appropriate time (such as crosswalks, stoplights, stop signs, and other locations), maintain proper lane position for the vehicle 105, and plan vehicle maneuvers along the driving path (such as when to make a turn, positioning the vehicle 105 in the proper lane for turning, activating vehicle turn signals, and the like), and other functions. The plurality of vehicle systems 110 may also include a plurality of sensors used for object detection, weather detection, light detection, and other functions.

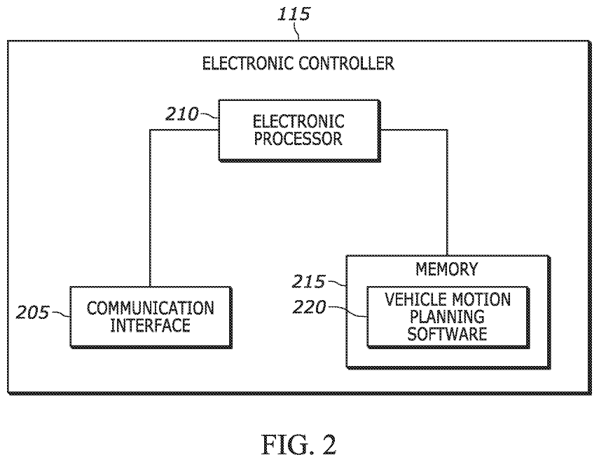

An example of the electronic controller 115 is illustrated in FIG. 2. The electronic controller 115 is communicatively coupled to other vehicle systems 110. The electronic controller 115 includes a communication interface 205, an electronic processor 210, and a memory 215. The communication interface 205 allows the electronic processor 210 to communicate with external hardware, such as the vehicle systems 110. The electronic processor 210 is communicatively coupled to the communication interface 205 and the memory 215. The electronic processor 210 is configured to access the memory 215 and, among other things, execute instructions for the system 100. The electronic processor 210 may be a microprocessor, an application-specific integrated circuit, or a similar processing circuit. The memory 215 is a non-transitory, computer-readable medium and contains instructions that, amongst other things, perform the methods and functions described herein when executed by the electronic processor 210.

In one embodiment, the memory 215 includes vehicle motion planning software 220. The vehicle motion planning software 220 allows the electronic controller 115 to plan a driving route for the vehicle 105 based upon input from the plurality of vehicle systems 110 and other inputs. For example, the vehicle motion planning software 220 may include a manifold describing the surface the vehicle 105 is driving on.

A manifold is an n-dimensional topological space for which every point is locally Euclidean. In other words, for every point in the manifold, there exists a neighborhood for that point that locally represents Euclidean space. For example, the surface of the Earth is a two-dimensional closed surface of representing a sphere. However, when standing at a point on Earth, the local topography appears to be a two-dimensional plane. In general, the surface is a two-dimensional, generally Euclidean space embedded in three-dimensional space

A manifold can therefore be described using a series of n dimensional charts. In this case, because the driving surface is represented as a two-dimensional space, a set of local two-dimensional charts can be obtained to represent the driving surface. For vehicle motion planning, the driving surface can be divided into a series of segments, each of which corresponds to a local chart of the manifold.

The local charts normally include some overlap. However, in this parameterization, it is assumed that a common boundary exists between consecutive local charts (e.g., between consecutive road segments). Because we assume that a common boundary exists between consecutive local charts, there exists a transformation between the boundaries. Therefore, local charts are chosen such that these corresponding boundaries are similar to each other, and the transformation between each consecutive local chart is approximately length preserving, which reduces or minimizes distortion around the driving path of the vehicle 105. A vehicle motion is then planned using the transformation between consecutive local charts. Because only consecutive charts share a common boundary, vehicle motions can only be planned between consecutive charts.

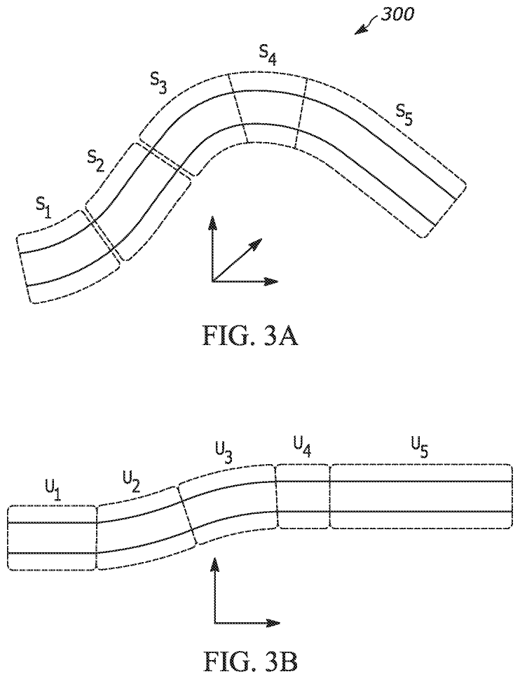

FIG. 3A illustrates a manifold 300 representing a three-dimensional driving surface according to one embodiment. The manifold 300 describes the three-dimensional driving surface using a plurality of road segments S₁-S₅. The road segments S₁-S₅ are then parameterized to obtain a plurality of two-dimensional local charts U₁-U₅ as illustrated in FIG. 3B. Each local chart of the plurality of two-dimensional local charts U₁-U₅ illustrates a plane located close to the road surface. The plane of each local chart can vary between consecutive road segments, which leads to gaps between the re-projected segments. These gaps correspond to stepwise changing roll and pitch along the driving surface. However, the error of these gaps can be kept small if the driving surface is assumed to not be very wide and if short segments are chosen.

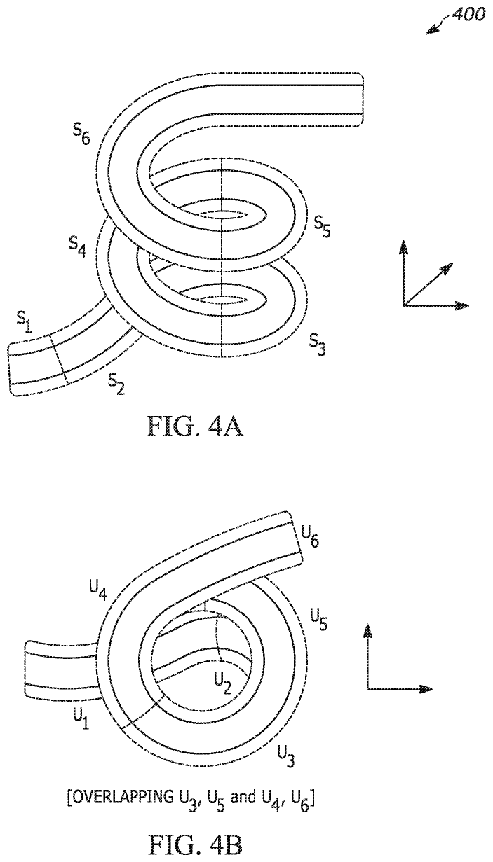

More complex road geometries can be illustrated using this parameterization. For example, FIG. 4A illustrates a manifold 400 representing a three-dimensional helix driving surface according to one embodiment. Road segments S₁-S₆ are illustrated by the manifold 400. After parameterization, a plurality of local charts U₁-U₆ are obtained as illustrated in FIG. 4B. While different charts may intersect, such as U₂ and U₄, they do not share a common boundary and are not consecutive local charts, and therefore a vehicle motion cannot be planned between the two. This corresponds to the respective road segments being at different vertical positions in the three-dimensional manifold 400 but located at substantially the same location for the two-dimensional projection. Therefore, vehicle motions can be determined based upon a transformation between U₂ and U₃, and U₃ and U₄, but not between U₂ and U₄.

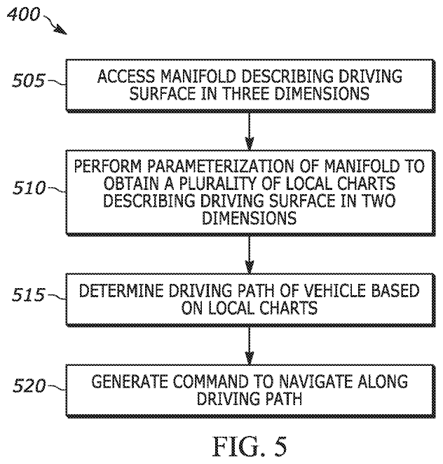

FIG. 5 illustrates a method 500 of determining a vehicle motion according to one embodiment. The example method 500 includes accessing, with the electronic controller 115, a manifold describing a driving surface in three dimensions (block 505). In one embodiment, the manifold is stored in the memory 215 alongside the vehicle motion planning software 220. In another embodiment, the electronic controller 115 uses the communication interface 205 to wirelessly communicate with a remote server to access the manifold describing the driving surface the vehicle 105 is currently traveling on. Because the manifold is stored as a three-dimensional representation of the driving surface, individual two-dimensional charts do not have to be stored for every road segment of the driving surface, thus saving memory and computing resources when planning vehicle motions.

The method 500 also includes performing, with the electronic controller 115, parameterization of the accessed manifold to obtain a plurality of local charts describing the driving surface in two dimensions (block 510). In one example, the driving surface may be stored in the memory 215 as a combination of a polygonal chain, or a connected series of line segments, and surface normals. This parameterization defines a frame at the beginning of each segment of the polygonal chain by aligning each segment with the x-direction, and aligning each surface normal with the z-direction of the frame. This gives frame transformations for consecutive segments of the polygonal chain, which then are converted into two-dimensional transformations. Chaining the two-dimensional transformations for each segment of the polygonal chain yields a parametrization of the driving surface.

The method 500 also includes determining, with the electronic controller 115, a driving path of the vehicle 105 based upon the plurality of local charts (block 515). For example, once the plurality of local charts have been obtained via parameterization, the electronic controller 115 determines a motion for the vehicle 105. This driving path may go through two or more consecutive local charts (such as charts U₂ and U₃ in FIG. 4B), but must occur between consecutive charts, and not intersecting charts. The vehicle motion and driving path may include any number of vehicle maneuvers, such as changing lanes, turning onto a different driving surface, slowing down and stopping at a stop sign, and other maneuvers.

Once the vehicle motion and driving path are determined, the electronic controller 115 is configured to generate a command to navigate along the driving path and/or execute the vehicle motion (block 520). For example, if the driving path includes a lane change, the electronic controller 115 generates a command to the plurality of vehicle systems 110 to activate a right turning signal of the vehicle 105, use a sensor to check for objects (such as other vehicles) in the desired lane, and then execute the lane change with a steering system. In another example, if the driving path includes a right turn onto a different driving surface, the electronic controller 115 generates a command to the plurality of vehicle systems 110 to slow the vehicle 105, activate a right turning signal of the vehicle 105, use a sensor to check that the turn is safe, execute the right turn onto the new driving surface, and then accelerate on the new driving surface.

The following examples illustrate example systems and methods described herein.

Example 1: A vehicle motion planning system, the system comprising an electronic controller configured to access a manifold describing a driving surface in three dimensions from a memory, perform parameterization of the manifold to obtain a plurality of local charts describing the driving surface in two dimensions, determine a driving path of a vehicle based using the plurality of local charts, and generate a command to navigate the vehicle along the driving path.

Example 2: the system of example 1, wherein the parameterization is approximately length preserving.

Example 3: the system of examples 1 or 2, wherein two consecutive local charts of the plurality of local charts share a common boundary.

Example 4: the system of example 3, wherein the driving path is determined based upon a transformation across the common boundary between the two consecutive local charts.

Example 5: the system of any of examples 1-4, wherein each local chart of the plurality of local charts corresponds to a road segment of the driving surface.

Example 6: the system of example 5, wherein two consecutive local charts of the plurality of local charts correspond to two consecutive road segments of the driving surface.

Example 7: the system of example 6, wherein the driving path can transition only between two consecutive road segments.

Example 8: the system of any of examples 1-7, wherein the parameterization projects a point of the manifold onto a plane of the driving surface to create at least one local chart of the plurality of local charts.

Example 9: the system of example 8, wherein variation in planes of two consecutive local charts of the plurality of local charts corresponds to changing roll and pitch along the driving surface.

Example 10: a method for planning a vehicle motion, the method comprising accessing, with an electronic controller, a manifold describing a driving surface in three dimensions from a memory; performing, with the electronic controller, parameterization of the manifold to obtain a plurality of local charts describing the driving surface in two dimensions; determining, with the electronic controller, a driving path of a vehicle based using the plurality of local charts; and generating, with the electronic controller, a command to navigate the vehicle along the driving path.

Example 11: the method of example 10, wherein the parameterization is approximately length preserving.

Example 12: the method of either example 10 or 11, wherein two consecutive local charts of the plurality of local charts share a common boundary.

Example 13: the method of example 12, wherein the driving path is determined based upon a transformation across the common boundary between the two consecutive local charts.

Example 14: the method of any of examples 10-13, wherein each local chart of the plurality of local charts corresponds to a road segment of the driving surface.

Example 15: the method of example 14, wherein two consecutive local charts of the plurality of local charts correspond to two consecutive road segments of the driving surface.

Example 16: the method of example 15, wherein the driving path can transition only between two consecutive road segments.

Example 17: the method of any of examples 10-16, wherein the parameterization projects a point of the manifold onto a plane of the driving surface to create at least one local chart of the plurality of local charts.

Example 18: the method of example 17, wherein variation in planes of two consecutive local charts of the plurality of local charts corresponds to changing roll and pitch along the driving surface.

Thus, embodiments described herein provide, among other things, systems and methods for planning vehicle motions based upon local road surface geometry. Various features, advantages, and embodiments are set forth in the following claims.

What is claimed is:

1. A vehicle motion planning system, the system comprising
an electronic controller configured to
access a manifold describing a driving surface in three dimensions from a memory,
perform parameterization of the manifold to obtain a plurality of local charts describing the driving surface in two dimensions,
determine a driving path of a vehicle using the plurality of local charts, and
generate a command to navigate the vehicle along the driving path.

2. The system of claim 1, wherein the parameterization is approximately length preserving.

3. The system of claim 1, wherein two consecutive local charts of the plurality of local charts share a common boundary.

4. The system of claim 3, wherein the driving path is determined based on a transformation across the common boundary between the two consecutive local charts.

5. The system of claim 1, wherein each local chart of the plurality of local charts corresponds to a road segment of the driving surface.

6. The system of claim 5, wherein two consecutive local charts of the plurality of local charts correspond to two consecutive road segments of the driving surface.

7. The system of claim 6, wherein the driving path can transition only between two consecutive road segments.

8. The system of claim 1, wherein the parameterization projects a point of the manifold onto a plane of the driving surface to create at least one local chart of the plurality of local charts.

9. The system of claim 8, wherein variation in planes of two consecutive local charts of the plurality of local charts corresponds to changing roll and pitch along the driving surface.

10. A method for planning a vehicle motion, the method comprising
accessing, with an electronic controller, a manifold describing a driving surface in three dimensions from a memory,
performing, with the electronic controller, parameterization of the manifold to obtain a plurality of local charts describing the driving surface in two dimensions,
determining, with the electronic controller, a driving path of a vehicle based using the plurality of local charts, and
generating, with the electronic controller, a command to navigate the vehicle along the driving path.

11. The method of claim 10, wherein the parameterization is approximately length preserving.

12. The method of claim 10, wherein two consecutive local charts of the plurality of local charts share a common boundary.

13. The method of claim 12, wherein the driving path is determined based upon a transformation across the common boundary between the two consecutive local charts.

14. The method of claim 10, wherein each local chart of the plurality of local charts corresponds to a road segment of the driving surface.

15. The method of claim 14, wherein two consecutive local charts of the plurality of local charts correspond to two consecutive road segments of the driving surface.

16. The method of claim 15, wherein the driving path can transition only between two consecutive road segments.

17. The method of claim 10, wherein the parameterization projects a point of the manifold onto a plane of the driving surface to create at least one local chart of the plurality of local charts.

18. The method of claim 17, wherein variation in planes of two consecutive local charts of the plurality of local charts corresponds to changing roll and pitch along the driving surface.
